(19) United States
(12) Patent Application Publication
(10) Pub. No.: US 2022/0108043 A1
(43) Pub. Date: Apr. 7, 2022

(54) Method and device for automatically generating residential building plan

(71) Applicant: Shenzhen XKool Technology CO., Ltd., Shenzhen (CN)

(72) Inventors: Xiaodi Yang, Shenzhen (CN); Chun Li, Shenzhen (CN)

(21) Appl. No.: 17/450,986

(22) Filed: Oct. 14, 2021

(51) Int. Cl. G06F 30/13; G06T 5/00; G06T 3/00; G06F 30/27

(52) U.S. Cl. CPC G06F 30/13; G06F 30/27; G06T 3/0081; G06T 5/002

(57) ABSTRACT

A method and device for automatically generating residential building plan, comprises: obtaining the standard plans of the residential buildings in each geographical region, analyzing the standard plans to obtain information on the construction area, residential unit area, unit layout, unit plan outline and functional composition and dimension corresponding to each of the standard plans as original training data; conducting training with original training data according to each geographical region in order to establish the residential building plan generative adversarial network model; receiving constraints and objective such as the target construction area, target residential unit area, target unit plan outline and target unit layout of the target residential building, generating residential unit plan model with functional zones based on the generative adversarial network model; denoising and trimming the residential unit plan model to obtain defined geometric information of residential building plan.

### TECHNICAL FIELD

The present disclosure relates to the technical field of residential building plan generation, specifically relates to a method and device for automatically generating residential building plan.

### BACKGROUND

As the important place for people to reside and live, residential building is getting more and more attention and concern, promoting the need to improve living quality level. As the real estate industry develops, there are more and more residential buildings, demand for residential unit design also keeps increasing. However, each user has different demand for residential unit design, how to satisfy each demand respectively for residential building design is very important.

Currently, to generate a residential building plan, it is primarily obtained from manual drawing by the designer using CAD (Computer Aided Design) tools such as AutoCAD of AutoDesk, the whole process is purely manual drawing design. The main disadvantage of conventional CAD design is slow process, almost the whole process involves manual participation, and the quality and speed of plan generation mostly depends on the experience and proficiency of the participant, large-scale and high variety output of residential building design drawings is not supported.

Another disadvantage is high error rate, different people may have different errors, even the same person can have different mistakes under different conditions, for example, when handling multiple projects simultaneously, or in case of poor physical strength and mental state. One more disadvantage is the high cost of modification, for human, one modification generally causes a great many relevant modifications, increasing time cost and error rate, let alone case of a large number of modifications.

Therefore, to those skilled in the art, how to provide a rational, efficient, accurate and batch-processing residential building plan generating scheme is an urgent technical problem to be solved.

### SUMMARY

The present disclosure provides a method and device for automatically generating residential building plan, in a bid to solve the design problem of the lack of rational, efficient, accurate and batch-processing residential building plan generation scheme in the prior art.

The present disclosure provides a method for automatically generating residential building plan, comprising:

acquiring the standard plans of the residential buildings in each geographical region, analyzing the standard plans to obtain information on the construction area, residential unit area, unit layout, unit plan outline and functional composition and dimension corresponding to each of the said standard plans as original training data;

conducting training by combining the original training data with the geographical region where such data come from to obtain the residential building plan generative adversarial network model;

receiving the target construction area, target residential unit area, target unit plan outline and target unit layout of the target residential building, generating residential unit plan model with functional zone based on the generative adversarial network model;

denoising and trimming the residential unit plan model to obtain defined geometric information of residential building plan.

Preferably, the method further comprises:

acquiring a preset residential building plan evaluation model;

evaluating the residential building plan based on the evaluation model to determine that wherein the neighboring functional zones are consistent with the neighboring relationship of the standard functional zones, and/or the area of the functional zones is within the geographical region of the corresponding standard functional zones, and/or all functional zones required have been provided, then confirming and outputting the residential building plan.

Preferably, the method further comprises:

acquiring the neighboring relationship of the functional zones in the standard plan of the residential building to conduct training in combination with the geographical region and corresponding unit layout of the corresponding residential building to obtain the functional zone neighboring relationship AI evaluation model;

obtaining the area of the functional zone in the standard plan of the residential building to conduct training in combination with the functional zone and corresponding unit layout of the corresponding residential building to obtain area AI evaluation model of the standard functional zone.

Preferably, where, denoising and trimming the residential unit plan model to obtain defined geometric information of residential building plan:

denoise and trim the residential unit plan model, remove deformed graphic using the area smoothing and snapping method, adjust and align the area angles;

optimize, denoise and trim the residential unit plan model based on the preset neighboring processing strategy of the functional zones to obtain defined geometric information of residential building plan.

Preferably, wherein the method further comprises:

obtaining the area of specific functional zone in the standard plan of the residential building, conducting training in combination with the geographical region and corresponding unit layout of the corresponding residential building to obtain area AI evaluation model of the specific functional zone;

based on the area AI evaluation model of the specific functional zone, evaluating the area of the specific functional zone of the residential building plan as minimum/maximum, confirming and outputting the residential building plan.

On the other hand, the present disclosure further provides a device for automatically generating residential building plan, comprising: training data acquisition module, model training module and residential building plan generating module; where,

The training data acquisition module is connected to the model training module to obtain the standard plans of the residential buildings in each geographical region, analyze the standard plans to obtain information on the construction area, residential unit area, unit layout, unit plan outline and functional composition and dimension corresponding to each of the standard plans as original training data;

The model training module, which is connected with the training data acquisition module and the residential building plan generating module, conducts training by combining the original training data with the geographical region where such data come from to obtain the residential building plan generative adversarial network model;

The residential building plan generating module is connected to the model training module to receive the target construction area, target residential unit area, target unit plan outline and target unit layout of the target residential building, and generate the residential unit plan model with functional zone based on the generative adversarial network model; denoise and trim the residential unit plan model to obtain defined geometric information of residential building plan.

Preferably, wherein the device further comprises: a residential building plan evaluation module, which is connected to the residential building plan generating module to obtain the preset residential building plan evaluation model;

evaluating the residential building plan based on the evaluation model to determine that wherein the neighboring functional zones are consistent with the neighboring relationship of the standard functional zones, and/or the area of the functional zones is within the geographical region of the corresponding standard functional zones, and/or all functional zones required have been provided, then confirming and outputting the residential building plan.

Preferably, wherein the device further comprises: residential building plan evaluation model training module, which is connected to the residential building plan evaluation module to obtain the neighboring relationship of the functional zone in the standard plan of the residential building, and conduct training in combination with the geographical region and the corresponding unit layout of the corresponding residential building to obtain the neighboring relationship AI evaluation model of the functional zone;

acquire the area of the functional zone in the standard plan of the residential building to conduct training in combination with the functional zone and corresponding unit layout of the corresponding residential building to obtain area AI evaluation model of the standard functional zone.

Preferably, wherein the residential building plan generating module comprises residential unit plan model generating unit and optimizing processing unit, where,

The residential unit plan generating unit is connected to the model training module and the optimizing processing unit to receive the target construction area, target residential unit area, target unit plan outline and target unit layout of the target residential building, and generate the residential unit plan model with functional zone based on the generative adversarial network model;

the optimizing processing unit is connected to the residential unit plan model generating unit to denoise and trim the residential unit plan model, remove deformed graphic using the area smoothing and snapping method, adjust and align the area angles;

optimize, denoise and trim the residential unit plan model based on the preset neighboring processing strategy of the functional zones to obtain defined geometric information of residential building plan.

Preferably, the device further comprises: a specific functional zone evaluation module, which is connected to the residential building plan generating module to obtain the area of the specific functional zone in the standard plan of the residential building, and conduct training in combination with the geographical region and the corresponding unit layout of the corresponding residential building to obtain the area AI evaluation model of the specific functional zone;

based on the area AI evaluation model of the specific functional zone, evaluate the area of the specific functional zone of the residential building plan as minimum/maximum, confirm and output the residential building plan.

The method and device for automatically generating residential building plan in the present disclosure adopt conventional graphic algorithm and deep learning to automatically generate residential building plan for use by the user. The input comprises geographical region, unit plan outline, functional zones composition, and number of housing units of the whole building floor plan. The output is the housing unit plan satisfying user's demand, the user can conduct further processing on the basis of the generated result, and then use it in standard CAD format. Comparing with the prior art, the algorithm of this scheme can be operated in the cloud without relying on a fixed platform, convenient and efficient. Meanwhile, based on the pure algorithm models, a great variety of residential building plans satisfying the standards input by the user can be output in seconds, greatly reducing the design time. Benefits, as follows, can be achieved: greatly improved speed (reducing design cost by over 95%); reduced design cost (reducing labor cost by over 70%); Lower error rate, higher accuracy; maximum compliance with local specification; diversity, finding better scheme as compared to conventional method.

### BRIEF DESCRIPTION OF DRAWINGS

In order to describe the technical solutions of the embodiments of the present disclosure, below is simple introduction to the figures used in the embodiment description of the present disclosure. Apparently, the figures described below are only some embodiments of the present disclosure, for those of ordinary skill in the art, other figures can also be obtained based on these figures without contribution of creative work.

FIG. 1 is the schematic flow chart of a method for automatically generating residential building plan in the embodiment of the present disclosure;

FIG. 2 is a schematic standard plan style of the automatically generating residential building plan in the embodiment of the present disclosure;

FIG. 3 is a schematic of selecting construction area, functional zones composition to generate editable housing unit from the automatically generated residential building plan in the embodiment of the present disclosure;

FIG. 4 is a schematic floor plan composed of different types of housing units in the automatically generated residential building plan in the embodiment of the present disclosure;

FIG. 5 is a schematic final adjusted floor plan of the automatically generated residential building plan in the embodiment of the present disclosure;

FIG. 6 is a marked residential building plan with training data as shown in the embodiment of the present disclosure;

FIG. 7 is a housing unit plan automatically generated by generative adversarial network as shown in the embodiment of the present disclosure;

FIG. 8 is the schematic flow chart of a second method for automatically generating residential building plan in the embodiment of the present disclosure;

FIG. 9 is the schematic flow chart of a third method for automatically generating residential building plan in the embodiment of the present disclosure;

FIG. 10 is the schematic flow chart of a fourth method for automatically generating residential building plan in the embodiment of the present disclosure;

FIG. 11 is the schematic flow chart of a fifth method for automatically generating residential building plan in the embodiment of the present disclosure;

FIG. 12 is the schematic structure of a device for automatically generating residential building plan in the embodiment of the present disclosure;

FIG. 13 is the schematic structure of a second device for automatically generating residential building plan in the embodiment of the present disclosure;

FIG. 14 is the schematic structure of a third device for automatically generating residential building plan in the embodiment of the present disclosure;

FIG. 15 is the schematic structure of a fourth device for automatically generating residential building plan in the embodiment of the present disclosure;

FIG. 16 is the schematic structure of a fifth device for automatically generating residential building plan in the embodiment of the present disclosure.

### DESCRIPTION OF EMBODIMENTS

Below is clear and complete description of the technical solutions in the embodiments of the present disclosure in conjunction with the figures of such embodiments, apparently, the embodiments described are some embodiments of the present disclosure only rather than all embodiments. Any other embodiment obtained by those of ordinary skill in the art based on the embodiments of the present disclosure without contribution of creative work is also within the protective scope of the present disclosure.

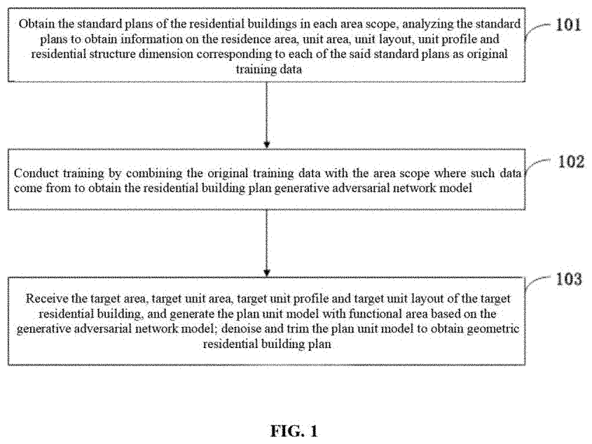

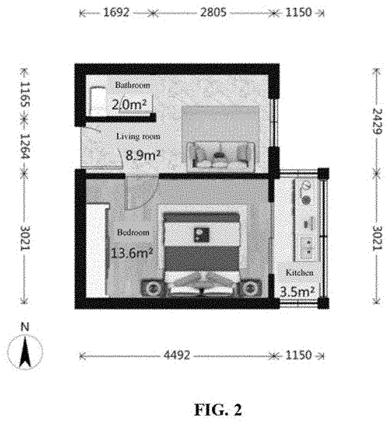

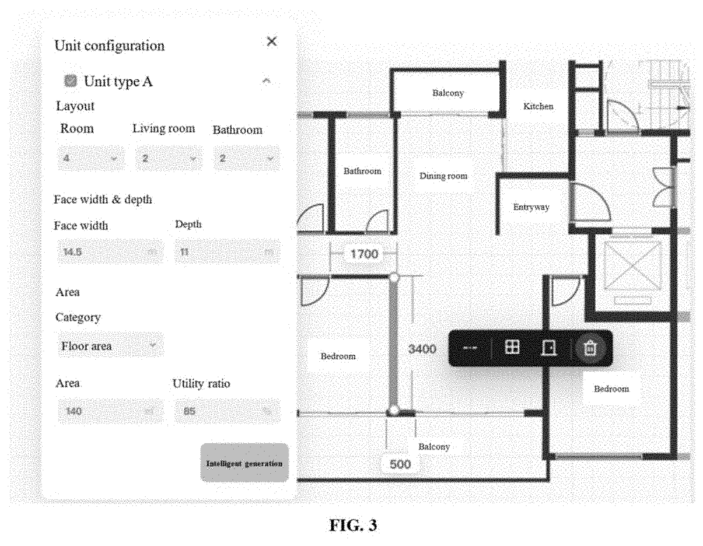

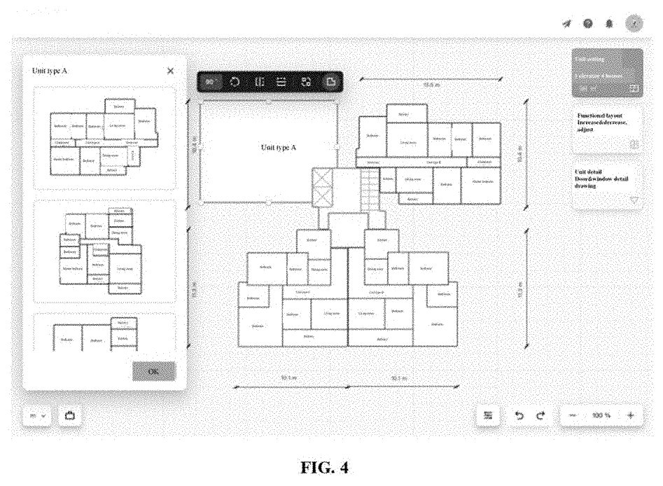

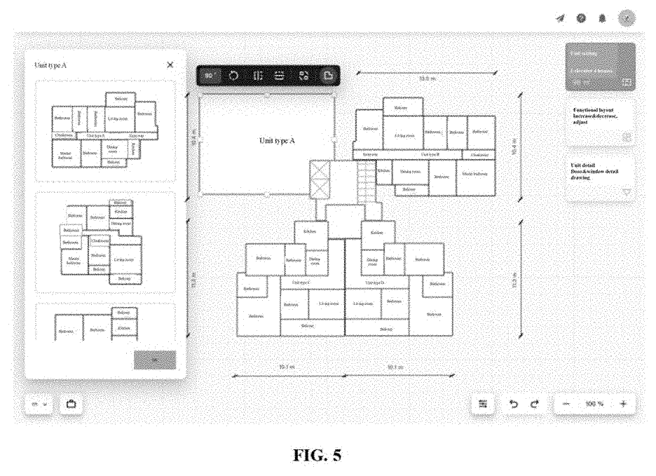

In the method for automatically generating a residential building plan in this embodiment, the result obtained and generated from learning tens of thousands of standard plans through the training model not only ensures diversity and compliance with standard specification, but also generates different results in accordance with different geographical region and/or municipal specifications, and the standard plan style comprises attribute, length and width. As shown in FIG. 1-5, FIG. 1 is the schematic flow chart of a method for automatically generating residential building plan in this embodiment; FIG. 2 is a schematic standard plan style of the automatically generated residential building plan in this embodiment; FIG. 3 is a schematic of selecting area, rooms and layout to generate editable residential unit from the automatically generated residential building plan in this embodiment; FIG. 4 is a schematic floor spliced by different types of units in the automatically generated residential building plan in this embodiment; FIG. 5 is a schematic final adjusted floor of the automatically generated residential building plan in this embodiment. Specifically, the method comprises steps as follows:

Step 101, acquiring the standard plans of the residential buildings in each geographical region, analyzing the standard plans to obtain information on the construction area, residential unit area, unit layout, unit plan outline and functional composition and dimension corresponding to each of the said standard plans as original training data;

Step 102, conducting training with the original training data according to geographical region where such data come from to obtain the residential building plan generative adversarial network model;

Step 103, receiving the objective parameters such as target construction area, target residential unit area, target unit plan outline and target unit layout of the target residential building, and generate the residential unit plan model with functional zone based on the generative adversarial network model; denoise and trim the generative model to obtain defined geometric information of residential building plan.

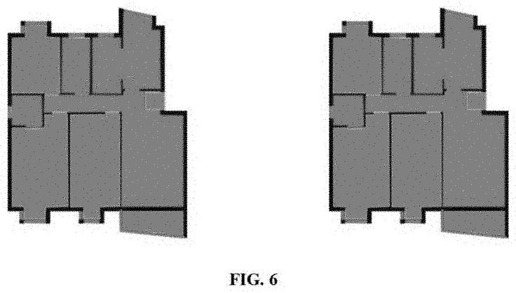

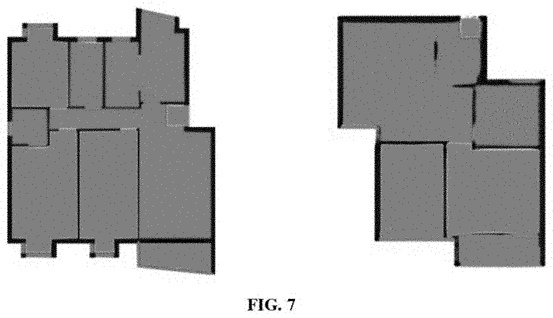

Based on the method for automatically generating residential building plan in this embodiment, to make any modification, just simply edit the parameters, then the modified result can be immediately obtained. This method can be used in the cloud, first, the data set collects tens of thousands of unit plans of the recent 10 years in China, wherein including many original training data for units with 1 to 5 rooms, then conduct labelling of functional zones to such training data. Using these data with labelling, the AI engineer goes through deep learning and automatically generates different unit types primarily using generative adversarial network technology. For example, FIG. 6 shows a marked residential building plan with training data, FIG. 7 shows a unit plan automatically generated by generative adversarial network.

For the trained generative adversarial network model, the user needs to input:

a. Residential unit area; b. Unit plan outline; c. the rooms for unit layout. The model will automatically generate a residential unit plan model with the functional zone. However, the model still has some noises, post treatment graphic algorithm graphic will denoise and trim the already generated polygon model to obtain a geometric plan. Wherein the graphic algorithm for post treatment primarily comprises a. area smoothing b. snapping areas. Denoising and trimming are to remove some deformed graphics generated by GANs, adjust and align the area angles.

Next, evaluate whether the generated result complies with specification requirements using the evaluation model, if not, eliminate the result (it is preset that multiple different AI models generate multiple different results). If satisfies, doors and windows will be further generated, then the result of the algorithm will be generated for the user. The main points to be evaluated by the evaluation model: a. whether the neighboring functional zones are rational; b. whether a certain specific functional zone is rational; c. whether the corridor area reaches the minimum area usable; d. whether all required function zones have been generated.

In some optional embodiments, as shown in FIG. 8, it is the schematic flow chart of a second method for automatically generating residential building plan in this embodiment, different from FIG. 1, further comprises:

Step 201, acquiring preset residential building plan evaluation model.

Step 202, evaluating the residential building plan based on the evaluation model to determine that wherein the neighboring functional zones are consistent with the neighboring relationship of the standard functional zones, and/or the area of the functional zones is within the geographical region of the corresponding standard functional zones, and/or all functional zones required have been provided, then confirm and output the residential building plan.

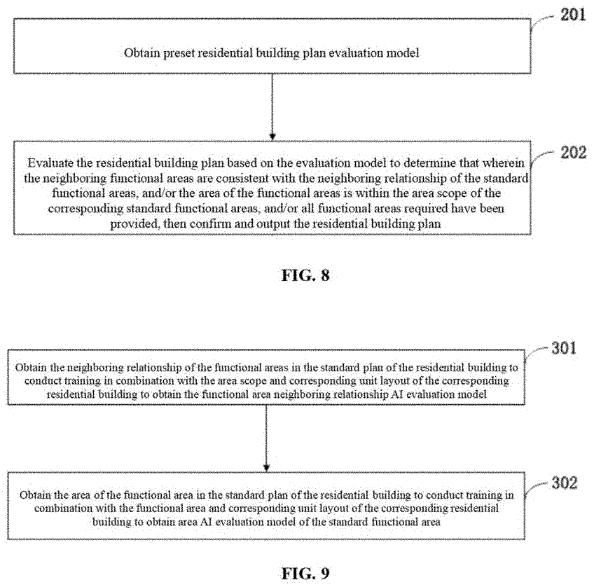

In some optional embodiments, as shown in FIG. 9, it is the schematic flow chart of a third method for automatically generating residential building plan in this embodiment, different from FIG. 8, further comprises:

Step 301, acquiring the neighboring relationship of the functional zones in the standard plan of the residential building to conduct training in combination with the geographical region and corresponding unit layout of the corresponding residential building to obtain the functional zone neighboring relationship AI evaluation model. AI model means artificial intelligence model.

Step 302, obtain the area of the functional zone in the standard plan of the residential building to conduct training in combination with the functional zone and corresponding unit layout of the corresponding residential building to obtain area AI evaluation model of the standard functional zone.

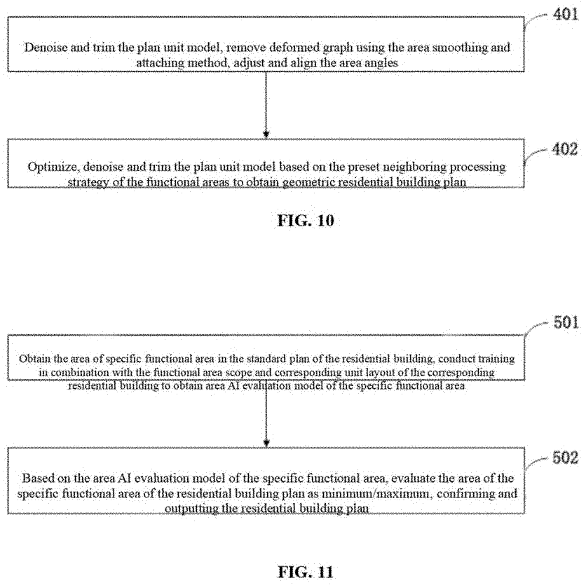

In some optional embodiments, as shown in FIG. 10, it is the schematic flow chart of a fourth method for automatically generating residential building plan in this embodiment, different from FIG. 1, the residential unit plan model is denoised and trimmed to obtain defined geometric information of residential building plan:

Step 401, denoising and trimming the residential unit plan model, remove the deformed graphic using the area smoothing and snapping method, adjust and align the area angles.

Step 402, optimizing, denoising and trimming the residential unit plan model based on the preset neighboring processing strategy of the functional zones to obtain defined geometric information of residential building plan.

In some optional embodiments, as shown in FIG. 11, it is the schematic flow chart of a fifth method for automatically generating residential building plan in this embodiment, different from FIG. 1, further comprises:

Step 501, acquiring the area of the specific functional zone in the standard plan of the residential building to conduct training in combination with the functional zone and corresponding unit layout of the corresponding residential building to obtain area AI evaluation model of the specific functional zone.

Step 502, based on the area AI evaluation model of the specific functional zone, evaluating the area of the specific functional zone of the residential building plan as minimum/maximum, confirming and outputting the residential building plan.

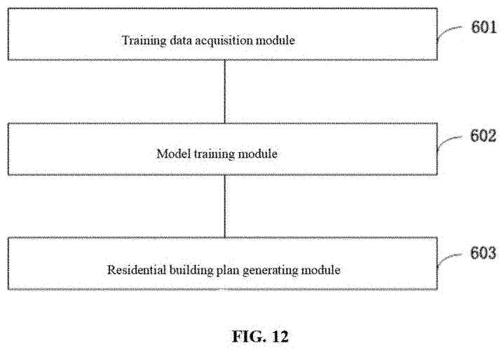

In some optional embodiments, as shown in FIG. 12, it is the schematic structure of a device for automatically generating residential building plan in this embodiment, the device can be used to implement the method for automatically generating residential building plan described above. Specifically, the device comprises training data acquisition module 601, model training module 602 and residential building plan generating module 603.

Where, the training data acquisition module 601 is connected to the model training module 602 to obtain the standard plans of the residential buildings in each geographical region, analyze the standard plans to obtain information on the construction area, residential unit area, unit layout, unit plan outline and functional composition and dimension corresponding to each of the standard plans as original training data.

The model training module 602, which is connected with the training data acquisition module 601 and the residential building plan generating module 603, conducts training by combining the original training data with the geographical region where such data come from to obtain the residential building plan generative adversarial network model.

The residential building plan generating module 603 is connected to the model training module 602 to receive the target construction area, target residential unit area, target unit plan outline and target unit layout of the target residential building, and generate the residential unit plan model with functional zone based on the generative adversarial network model; denoise and trim the residential unit plan model to obtain defined geometric information of residential building plan.

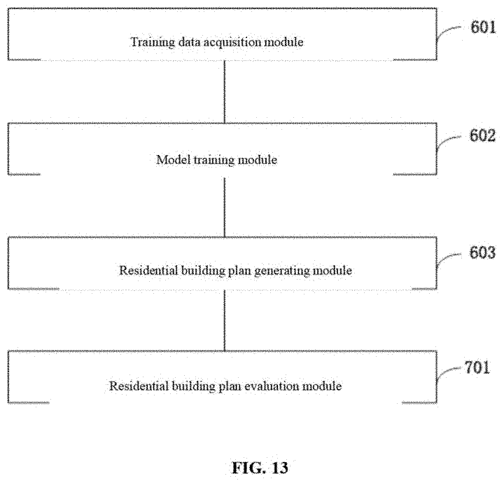

In some optional embodiments, as shown in FIG. 13, it is the schematic structure of a second device for automatically generating residential building plan in this embodiment, different from FIG. 12, further comprises: residential building plan evaluation module 701, which is connected to the residential building plan generating module 603 to obtain the preset residential building plan evaluation model; evaluating the residential building plan based on the evaluation model to determine that wherein the neighboring functional zones are consistent with the neighboring relationship of the standard functional zones, and/or the area of the functional zones is within the geographical region of the corresponding standard functional zones, and/or all functional zones required have been provided, then confirming and outputting the residential building plan.

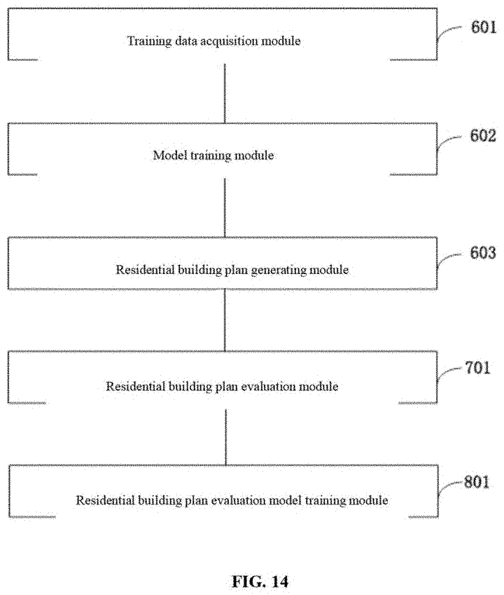

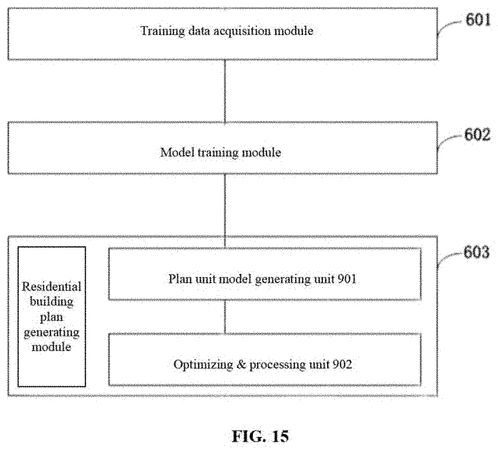

In some optional embodiments, as shown in FIG. 14, it is the schematic structure of a third device for automatically generating residential building plan in this embodiment, different from FIG. 13, further comprises: residential building plan evaluation model training module 801, which is connected to the residential building plan evaluation module 701 to obtain the neighboring relationship of the functional zone in the standard plan of the residential building, and conduct training in combination with the geographical region and the corresponding unit layout of the corresponding residential building to obtain the neighboring relationship AI evaluation model of the functional zone.

Obtaining the area of the functional zone in the standard plan of the residential building to conduct training in combination with the functional zone and corresponding unit layout of the corresponding residential building to obtain area AI evaluation model of the standard functional zone.

The residential unit plan generating unit 901 is connected to the model training module 602 and the optimizing processing unit 902 to receive the target construction area, target residential unit area, target unit plan outline and target unit layout of the target residential building, and generate the residential unit plan model with functional zone based on the generative adversarial network model.

The optimizing processing unit 902 is connected to the residential unit plan model generating unit 901 to denoise and trim the residential unit plan model, remove deformed graphic using the area smoothing and snapping method, adjust and align the area angles. Optimize, denoise and trim the residential unit plan model based on the preset neighboring processing strategy of the functional zones to obtain defined geometric information of residential building plan.

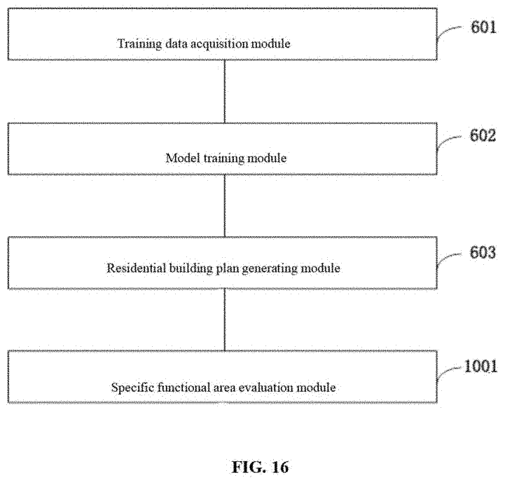

In some optional embodiments, as shown in FIG. 16, it is the schematic structure of a fifth device for automatically generating residential building plan, different from FIG. 12, further comprises: specific functional zone evaluation module 1001, which is connected to the residential building plan generating module 603 to obtain the area of the specific functional zone in the standard plan of the residential building, and conduct training in combination with the geographical region and the corresponding unit layout of the corresponding residential building to obtain the area AI evaluation model of the specific functional zone.

Based on the area AI evaluation model of the specific functional zone, evaluating the area of the specific functional zone of the residential building plan as minimum/maximum, confirming and outputting the residential building plan.

Artificial Intelligence, abbreviated as AI, enables computers to simulate certain human thought processes and intelligent behaviors (such as learning, reasoning, thinking and planning), mainly including the principles of computers to achieve intelligence, manufacturing computers similar to the intelligence of the human brain, so that computers can achieve higher-level applications. The method is an easy-to-use cloud tool integrating multiple advanced technologies such as artificial intelligence, big data and smart display for automatically generating residential building plan, which can help designers easily complete automatic generation of residential building plan under various conditions, and support real-time modification feedback, what you see is what you get. After getting the result, user can edit the parameters of the residential building as they like, and the automatically generated residential building plan result updates in real time, editing building parameters and returning new residential building plan result is not a repeated interaction process anymore, user can obtain the latest result upon modification.

This embodiment can further comprise a computer device comprising memory, processor, and computer program stored in the memory and operable on the processor, the processor executes the computer program to implement the steps of automatically generating residential building plan as described above.

A readable storage medium storing computer program, wherein the steps of automatically generating residential building plan as described above are implemented when the computer program is executed by the processor.

It can be understood by those of ordinary skill in the art that the whole or part of the process of the method in the above embodiment, it can be implemented by computer program instructing relevant hardware, the computer program can be stored in a non-volatile storage medium readable by computer, the execution of the computer program can comprise the processes in the embodiments of the methods described above. Where, any reference to memory, storage, database or other medium in the embodiments provided in this application may include both non-volatile memory and/or volatile memory. Non-volatile memory may include read-only memory (ROM), programmable ROM (PROM), electrically programmable ROM (EPROM), electrically erasable and programmable ROM (EEPROM) or flash memory. Volatile memory may include random access memory (RAM) or external cache memory. As illustration rather than limitation, RAM is available in many forms such as static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM).

Those skilled in the art can clearly understand that, for the convenience of concise description, only examples of the functional units and modules described above are given, in actual application, such functions described above can be assigned to different functional units and modules for completion based on the need, i.e., internal construction of the device can be divided into different functional units or modules to complete all or partial functions described above.

Embodiments described above are merely provided for description of the technical solutions of the present disclosure rather than limitation. Although the present disclosure has been described in detail in reference to the above embodiments, those of ordinary skill in the art shall understand that they can still modify the technical solutions described in the above embodiments, or conduct equivalent replacement to some technical features therein; but such modifications or replacements will not make the nature of the relevant technical solutions depart from the spirit and scope of the technical solution in the embodiments of the present disclosure, and shall be included in the protection scope of the present disclosure.

What is claimed is:

1. A method for automatically generating residential building plan, wherein comprising:
obtaining the standard plans of the residential buildings in each geographical region, analyzing the standard plans to obtain information on the construction area, residential unit area, unit layout, unit plan outline and functional composition and dimension corresponding to each of the said standard plans as original training data;
conducting training with the original training data according to each geographical region where such data come from to obtain the residential building plan generative adversarial network model;
receiving objective parameters such as the target construction area, target residential unit area, target unit plan outline and target unit layout of the target residential building, generating residential unit plan model with functional zones based on the generative adversarial network model;
denoising and trimming the residential unit plan model to obtain defined geometric information of residential building plan.

2. The method for automatically generating residential building plan according to claim 1, wherein further comprises:
obtaining preset residential building plan evaluation model;
evaluating the residential building plan based on the evaluation model to determine that wherein the neighboring functional zones are consistent with the neighboring relationship of the standard functional zones, and/or the construction area of one functional zone is within the construction area of the corresponding standard functional zone, and/or all functional zones required have been provided, then confirming and outputting the residential building plan.

3. The method for automatically generating residential building plan according to claim 2, wherein further comprises:
obtaining the neighboring relationship of the functional zones in the standard plan of the residential building to conduct training in combination with the geographical region and corresponding unit layout of the corresponding residential building to obtain the functional zones neighboring relationship AI evaluation model;
obtaining the construction area of the functional zone in the standard plan of the residential building to conduct training in combination with the geographical region and corresponding unit layout of the corresponding residential building to obtain construction area AI evaluation model of the standard functional zone.

4. The method for automatically generating residential building plan according to claim 1, wherein the residential unit plan model is denoised and trimmed to obtain defined geometric information of residential building plan:
denoise and trim the residential unit plan model, remove deformed graphic using the area smoothing and snapping method, adjust and align the area angles;
optimize, denoise and trim the residential unit plan model based on the preset neighboring processing strategy of the functional zones to obtain defined geometric information of residential building plan.

5. The method for automatically generating residential building plan according to claim 1, wherein further comprises:
obtaining the construction area of specific functional zone in the standard plan of the residential building, conducting training in combination with the geographical region and corresponding unit layout of the corresponding residential building to obtain area AI evaluation model of the specific functional zone;
based on the area AI evaluation model of the specific functional zone, evaluating the area of the specific functional zone of the residential building plan as minimum/maximum, confirming and outputting the residential building plan.

6. A device for automatically generating residential building plan, wherein comprises: training data acquisition module, model training module and residential building plan generating module; wherein,
the training data acquisition module is connected to the model training module to obtain the standard plans of the residential buildings in each geographical region, analyze the standard plans to obtain information on the construction area, residential unit area, unit layout, unit plan outline and functional composition and dimension corresponding to each of the standard plans as original training data;
the model training module, which is connected with the training data acquisition module and the residential building plan generating module, conducts training by combining the original training data with the geographical region where such data come from to obtain the residential building plan generative adversarial network model;
the residential building plan generating module is connected to the model training module to receive the target construction area, target residential unit area, target unit plan outline and target unit layout of the target residential building, and generate the residential unit plan model with functional zone based on the generative adversarial network model; denoise and trim the residential unit plan model to obtain defined geometric information of residential building plan.

7. The device for automatically generating residential building plan according to claim 6, wherein further comprises: residential building plan evaluation module, which is connected to the residential building plan generating module to obtain the preset residential building plan evaluation model;
evaluating the residential building plan based on the evaluation model to determine that wherein the neighboring functional zones are consistent with the neighboring relationship of the standard functional zones, and/or the area of the functional zones is within the geographical region of the corresponding standard functional zones, and/or all functional zones required have been provided, then confirming and outputting the residential building plan.

8. The device for automatically generating residential building plan according to claim 7, wherein further comprises: residential building plan evaluation model training module, which is connected to the residential building plan evaluation module to obtain the neighboring relationship of the functional zone in the standard plan of the residential building, and conduct training in combination with the geographical region and the corresponding unit layout of the corresponding residential building to obtain the neighboring relationship AI evaluation model of the functional zone;
obtaining the area of the functional zone in the standard plan of the residential building to conduct training in combination with the functional zone and corresponding unit layout of the corresponding residential building to obtain area AI evaluation model of the standard functional zone.

9. The device for automatically generating residential building plan according to claim 6, wherein the residential building plan generating module comprises residential unit plan model generating unit and optimizing processing unit, wherein,
the residential unit plan generating unit is connected to the model training module and the optimizing processing unit to receive the target construction area, target residential unit area, target unit plan outline and target unit layout of the target residential building, and generate the residential unit plan model with functional zone based on the generative adversarial network model;
the optimizing processing unit is connected to the residential unit plan model generating unit to denoise and trim the residential unit plan model, remove deformed graphic using the area smoothing and snapping method, adjust and align the area angles;
optimize, denoise and trim the residential unit plan model based on the preset neighboring processing strategy of the functional zones to obtain defined geometric information of residential building plan.

10. The device for automatically generating residential building plan according to claim 6, wherein further comprises: specific functional zone evaluation module connected to the residential building plan generating model to obtain the area of the specific functional zone in the standard plan of the residential building, to conduct training in combination with the geographical region and the corresponding unit layout of the corresponding residential building to obtain the area AI evaluation model of the specific functional zone;
based on the area AI evaluation model of the specific functional zone, evaluating the area of the specific functional zone of the residential building plan as minimum/maximum, confirming and outputting the residential building plan.
